(19) United States
(12) Patent Application Publication
(10) Pub. No.: US 2007/0154852 A1
(43) Pub. Date: Jul. 5, 2007

(54) METHOD FOR PATTERNING A THIN FILM USING A PLASMA BY-PRODUCT

(76) Inventor: Jeong Yel Jang, Gyeonggi-do (KR)

Correspondence Address: SHERR & NOURSE, PLLC, 620 HERNDON PARKWAY, SUITE 200, HERNDON, VA, 20170, US

(21) Appl. No.: 11/617,186

(22) Filed: Dec. 28, 2006

(30) Foreign Application Priority Data
Dec. 29, 2005 (KR) 10-2005-0134309
Dec. 29, 2005 (KR) 10-2005-0134313
Dec. 29, 2005 (KR) 10-2005-0134238

(51) Int. Cl. G03F 7/26

(52) U.S. Cl. 430/322; 430/327

(57) ABSTRACT

Embodiments relate to a method of patterning a thin film using a by-product of plasma. According to embodiments, the method may include (a) forming a thin film serving as a target object to be etched on a substrate, (b) forming photoresist patterns on the thin film, (c) performing a plasma treatment with respect to the photoresist pattern such that a by-product is attached to an outer wall of the photoresist pattern, and (d) patterning the thin film by using the photoresist patterns attached with the by-product as an etching mask. In embodiments, when a by-product of plasma is attached to a photoresist pattern such that the by-product of plasma is used as an etching mask, the thickness of the by-product may be formed as a desired thickness by controlling process variables.

The present application claims priority under 35 U.S.C. 119 and 35 U.S.C. 365 to Korean Patent Application Nos. 10-2005-0134309 (filed on Dec. 29, 2005), 10-2005-0134313 (filed on Dec. 29, 2005), and 10-2005-0134238 (filed on Dec. 29, 2005), each of which is hereby incorporated by reference in its entirety.

### BACKGROUND

Semiconductor devices may be formed on a substrate by repeatedly performing a thin film process (e.g., chemical vapor deposition, physical vapor deposition, oxidation and the like), a photo process, an etching process, and the like. Photo process technology may refer to a technology for implementing patterns designed on a mask on a wafer in accordance with process control standards. To this end, light having a specific wavelength may be exposed on a substrate that may be coated with a photosensitizer through a mask formed with a pattern. A photochemical reaction may be caused by the photosensitizer, and a photoresist pattern may be formed through a chemical reaction in the subsequent development process. A lower layer may be etched through the photoresist pattern formed in such a manner, thereby transferring a mask pattern onto the lower layer.

As semiconductor devices have become highly integrated, pattern sizes of IC devices have been greatly decreased. Particularly, in a case of flash memory devices, a design standard has been decreased by 130 nm. Accordingly a process technology for forming micro-patterns has been developed.

A flash memory is a kind of PROM (Programmable ROM) that may be capable of electrically re-writing data. The flash memory may realize a program input scheme of an erasable PROM (EPROM) and an erase scheme of an electrically erasable PROM (EEPROM) using one transistor by combining the advantages of an EPROM and the EEPROM. Flash memory may be referred to as a nonvolatile memory since stored information may not be erased even when power is turned off. This may be different from a dynamic RAM (DRAM) or a static RAM (SRAM).

Flash memory may be divided into a NOR-type structure, in which cells may be arranged in a row between a bit line and a ground, and a NAND-type structure, in which cells maybe arranged in series between the bit line and the ground. Since the NOR-type flash memory, which may have a parallel structure, may perform high speed random access when a reading operation is performed, the NOR-type flash memory may be used for various applications, including booting a mobile telephone.

The NAND-type flash memory, which may have a serial structure, may have low reading speed but high writing speed. Hence, the NAND-type flash memory may be suitable for storing data and may be suited to miniaturization.

The flash memory may be divided into a stack gate type and a split gate type in accordance with a structure of a unit cell and may be divided into a floating gate device and a silicon-oxide-nitride-oxide-silicon (SONOS) device in accordance with the shape of a charge storage layer.

Among them, a performance of a floating gate device may be dependent on the area of a floating gate. Particularly, the distance between floating gate lines has been gradually decreased and may be formed by 100 nm or less. Light sources having a short wavelength, such as ArF excimer lasers, may be used to form the distance between gate lines by 100 nm or less using a related art photo process. However, since ArF excimer laser equipment may be expensive, manufacturing costs of semiconductor devices may increase when this equipment is used.

Instead of using high-priced exposure equipment, a method of reducing the distance between floating gates using a hard mask may be used. FIGS. 1a to 1d illustrate a process of forming a floating gate electrode by using a hard mask.

Referring to FIG. 1a, polycrystalline silicon layer 14, which may be used to form a floating gate, may be formed on semiconductor substrate 10 formed with tunnel oxide layer 12. Hard mask layer 16 may be formed on polycrystalline silicon layer 14, and photoresist patterns 18 may be formed through a photo process. Hard mask layer 16 may be partially etched using photoresist patterns 18 as an etching mask, thereby forming hard mask patterns 16a as shown in FIG. 1b.

Spacer forming layer 17 may be formed on top surfaces of hard mask patterns 16a and polycrystalline silicon layer 14 exposed by removing a portion of hard mask layer 16. After that, if a blank etching process is performed with respect to spacer forming layer 17, spacer 17a may be formed on a sidewall of hard mask pattern 16a as shown in FIG. 1c.

Polycrystalline silicon layer 14 may be patterned using hard mask patterns 16a and spacers 17a as an etching mask, thereby forming a plurality of floating gate electrodes 14a constituting a unit cell as shown in FIG. 1d.

Since distance D2 between floating gate electrodes 14a may be smaller than distance D1 between photoresist patterns 18 having been used to form initial hard mask pattern 16a, the aforementioned method has been used as an advantageous method in manufacturing devices with a critical dimension of 100 nm or less. However, since this process is complicated (including the process to manufacture hard mask patterns and spacers in the aforementioned method), a productivity of all products may be lowered.

### SUMMARY

Embodiments relate to a semiconductor device manufacturing technology. Embodiments relate to a method of patterning a thin film formed on a semiconductor substrate.

Embodiments relate to reducing a line distance between floating gates of a flash memory device without utilizing high-priced exposure equipment.

Embodiments relate to adjusting a critical dimension of a thin film using a by-product of plasma when patterning the thin film formed on a semiconductor substrate.

Embodiments relate to effectively preventing an occurrence of a step difference by etching a portion of a thin film in a process of etching an antireflective coating when patterning the thin film formed on a substrate in a photo process using the antireflective coating.

Embodiments relate to effectively preventing a bridge from being formed between by-products attached on adjacent photoresist patterns when attaching the by-products on the photoresist patterns.

In embodiments, a method of forming a thin film using a by-product of plasma may include (a) forming a thin film serving as a target object to be etched on a substrate; (b) forming photoresist patterns on the thin film; (c) performing a plasma treatment with respect to the photoresist pattern such that a by-product may be attached to an outer wall of the photoresist pattern; and (d) patterning the thin film by using the photoresist patterns attached with the by-product as an etching mask.

In embodiments, an antireflective coating may be further formed on the thin film. In embodiments, the photoresist patterns may be formed on the antireflective coating, and the antireflective coating may be patterned together with the thin film. In embodiments, C₅F₈ plasma and CCP (Capacitively Coupled Plasma) may be used in a plasma treatment of a photoresist layer. In embodiments, the thickness of the by-product attached to the photoresist patterns may be adjusted under the condition of pressure of 20 to 40 mTorr, C₅F₈ of 16 to 20 sccm, Ar of 70 to 130 sccm and RF power of 500 to 900 W.

### BRIEF DESCRIPTION OF THE DRAWINGS

FIGS. 1a to 1b are example sectional diagrams illustrating a related art method of patterning a floating gate using a hard mask to form a floating gate array of a flash memory device;

FIGS. 2a to 2c are example sectional diagrams illustrating a method of patterning a thin film using a by-product of plasma according to embodiments;

FIG. 3 is an example graph showing a change in thickness of a by-product depending on a process variable in a plasma process;

FIGS. 4a and 4b are example images of a CD-SEM for comparing thin film patterns formed through a method according to embodiments and a related art photo-etching process, respectively;

FIGS. 5a to 5d are example sectional diagrams illustrating a method of patterning a thin film using a by-product of plasma according to embodiments;

FIG. 6a is an image of a CD-SEM showing a state where a lower layer may be etched in a process of etching an antireflective coating such that a step difference occurs in a final thin film pattern according to embodiments;

FIG. 6b is an image of the CD-SEM showing a state where the occurrence of a step difference is prevented such that a desired thin film pattern may be formed through the method according to embodiments;

FIGS. 7a to 7d are example sectional diagrams illustrating a method of patterning a thin film using a by-product of plasma according to embodiments;

FIG. 8a is an example image of a CD-SEM showing a state where a by-product of plasma may be formed on a target object to be etched in a process of attaching the by-product of plasma on a photoresist pattern according to embodiments; and

FIG. 8b is an example image of the CD-SEM showing a state where a by-product of plasma is selectively formed on only a photoresist pattern through the method according to embodiments.

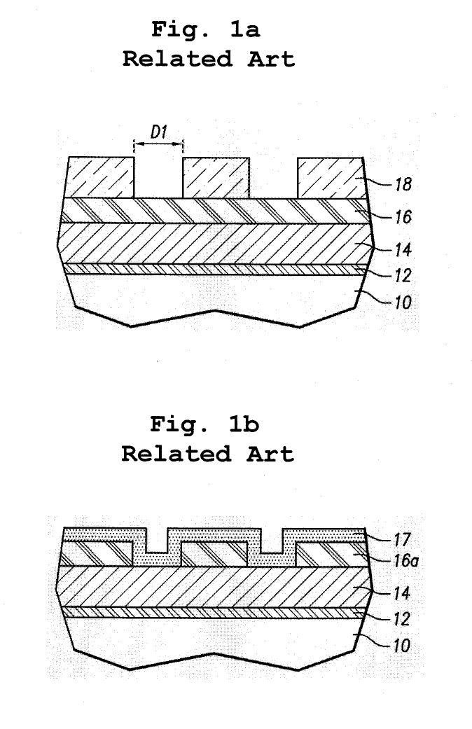

### DETAILED DESCRIPTION OF EMBODIMENTS

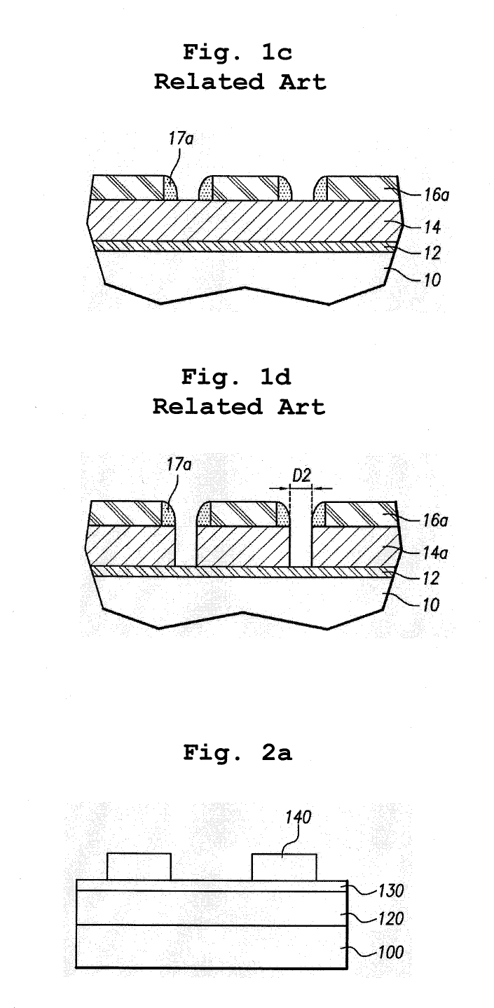

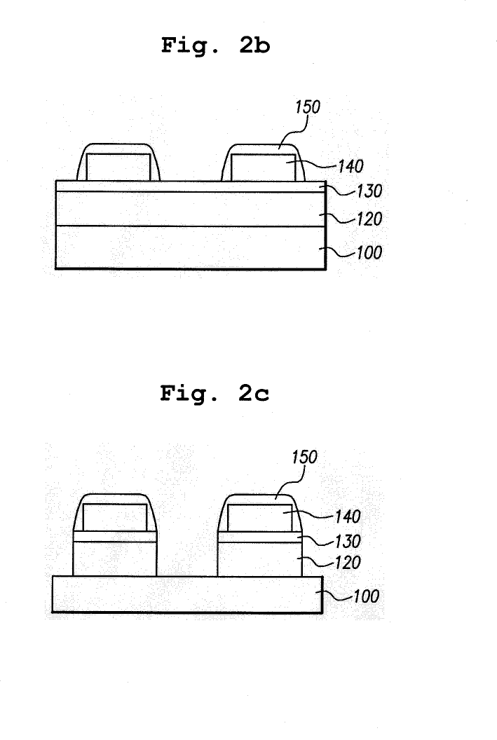

Referring to FIG. 2a, thin film 120, which may serve as a target object to be etched, may be formed on substrate 100. In embodiments, thin film 120 may be a polycrystalline silicon layer constituting floating gates of a flash memory device. In addition, thin film 120 may be various kinds of layers to be patterned at a fine distance, but a material of thin film 120 is not limited. Further, thin film 120 may be formed through physical vapor deposition, chemical physical vapor deposition, atomic layer deposition or the like depending on a property of its material, according to embodiments.

Photoresist patterns 140 may be formed on the thin film 120 through a general photo process. The distance between photoresist patterns 140 may be larger than the line distance between thin film patterns which will be finally formed. If the line distance between the final thin film patterns is set to be 100 nm, a distance between photoresist patterns 140 may be formed to be 100 nm or more. Although it will be described later, a distance between photoresist patterns 140 may be narrow as a desired line distance (100 nm) with a by-product of plasma.

In embodiments, if thin film 120 is formed with a metallic material, unexpected horizontal and vertical bends may be produced on a sidewall of a photoresist pattern due to the diffused reflection and high reflection of a substrate when developing the photoresist layer. This may influence subsequent processes. In embodiments, antireflective coating 130 may be formed on thin film 120 before forming photoresist patterns 140.

Referring to FIG. 2b, before performing an etching process of thin film 120, by-product 150, which may be produced by performing a plasma treatment with respect to photoresist patterns 140, may be attached to an outer wall of photoresist pattern 140. In embodiments, C₅F₈ plasma may be used in the plasma treatment. A CxFy based by-product may be produced due to a reaction between a photoresist layer and C₅F₈ plasma. Since a by-product may generally have high energy, the by-product may be in a very unstable state.

For this reason, a by-product may have a property in which the by product may return to a stable state while discharging its own energy. The by-product may be discharged to an outside of a process chamber in most processes. However, in embodiments, by-product 150 produced by appropriately controlling a process condition may be attached to the outer wall of photoresist pattern 140 in an appropriate thickness.

FIG. 3 illustrates a measured result of a change in thickness of a by-product attached to a photoresist pattern depending on a plasma treatment process condition as a graph. Here, CCP (Capacitively Coupled Plasma) type plasma equipment (DRM(Dipole Ring Magnetron) by TEL) is used in the plasma treatment. As shown in FIG. 3, assuming that process conditions include a process chamber pressure of 20 to 40 mTorr, C₅F₈ of 16 to 20 sccm, Ar of 70 to 130 sccm, and RF power of 500 to 900 W, a thickness of by-product 150 attached to photoresist pattern 140 is changed in a range of approximately 800 to 1100 Å. Particularly, it may be seen that a thickness of by-product 150 may be the most sensitive to pressure in process variables.

Referring to FIG. 2c, thin film 120 may be etched, for example using photoresist patterns 140 attached with by-product 150 as an etching mask. This may form thin film patterns spaced apart from one another at a prescribed interval. In embodiments, if antireflective coating 130 is formed on thin film 120, antireflective coating 130 may be first patterned, and the thin film may then be patterned.

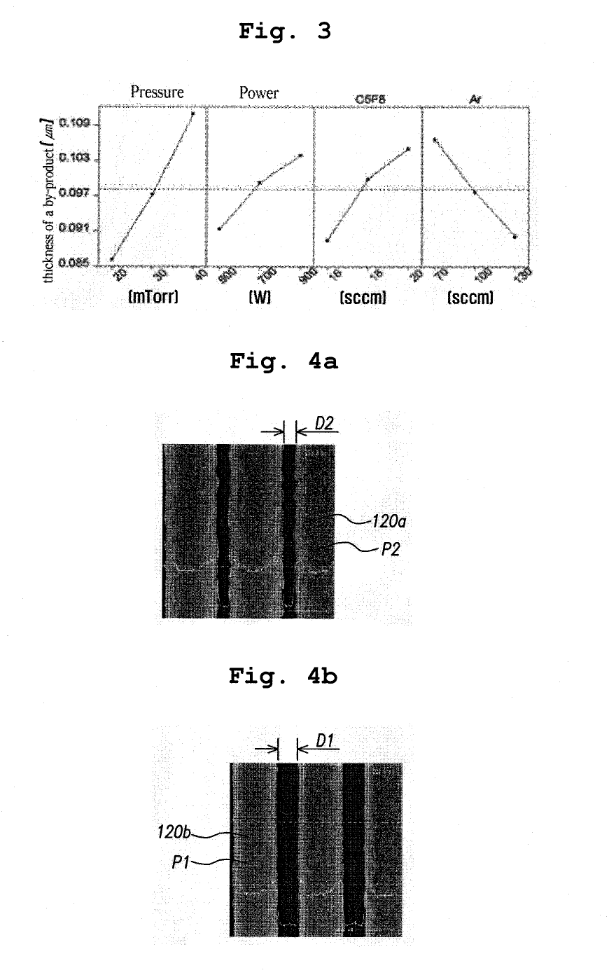

FIGS. 4a and 4b illustrate images of a CD-SEM (Critical Dimension Scanning Electron Microscopy) for thin film patterns 120a patterned through the aforementioned method and thin film patterns 120b patterned through a general photo process, respectively. As shown in FIGS. 4a and 4b, line distance D2 between thin film patterns 120a formed according to this embodiment may be formed to be much smaller than that D1 between thin film patterns 120b formed through a general photo process.

According to embodiments, floating gates may be formed at a desired line distance without necessitating high-priced exposure equipment when forming floating gates at a line distance of 100 nm or less in a semiconductor device, particularly a flash memory device. Particularly, if a by-product of plasma is attached to a photoresist pattern such that the by-product of plasma is used as an etching mask in embodiments, a thickness of the by-product may be formed as a desired thickness by controlling process variables.

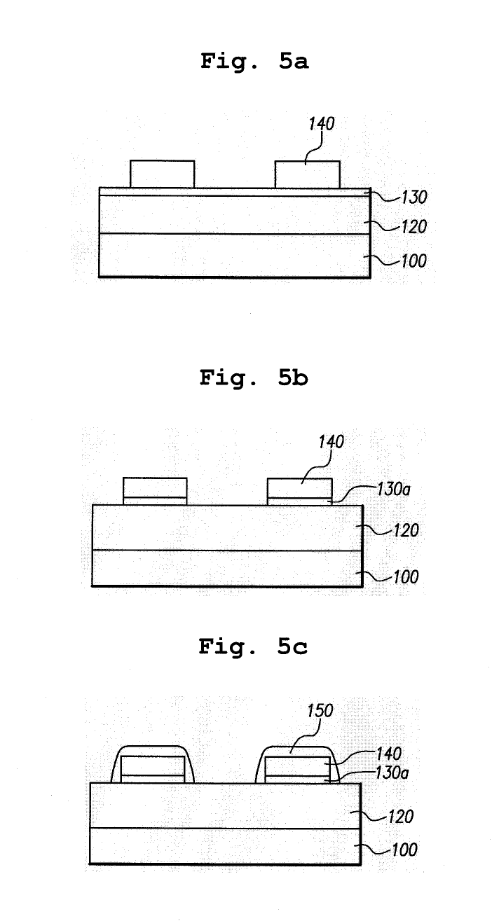

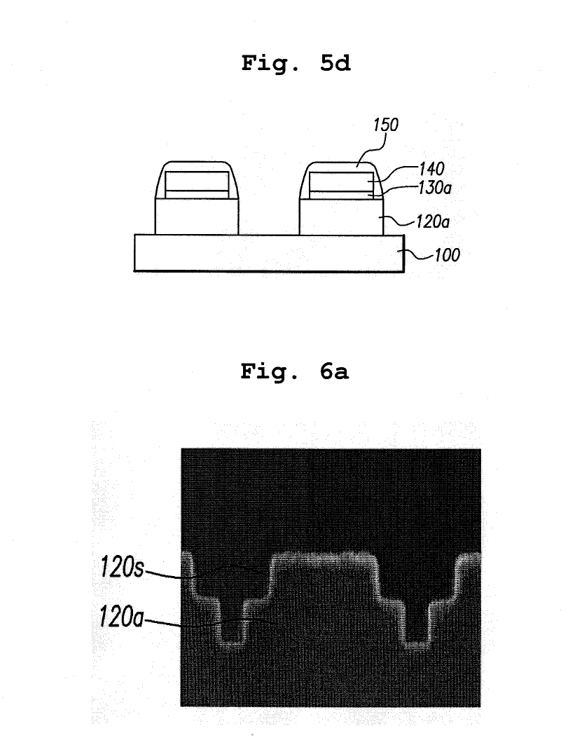

Referring to FIG. 5a, according to embodiments thin film 120, which may serve as a target object to be etched, may be formed on a substrate 100. Here, thin film 120 may be a polycrystalline silicon layer constituting floating gates of a flash memory device. In addition, thin film 120 may be various kinds of layers to be patterned at a fine distance, but a material of thin film 120 is not limited. Further, thin film 120 may be formed through physical vapor deposition, chemical physical vapor deposition, atomic layer deposition or the like depending on a property of its material.

When developing the photoresist layer in a following photo process, unexpected horizontal and vertical bends may be produced on a sidewall of a photoresist pattern due to the diffused reflection and high reflection of a substrate, which may influence subsequent processes. Thus, antireflective coating 130 may be formed on thin film 120 before forming a photoresist pattern.

Photoresist patterns 140 may be formed on the thin film 130 through a general photo process. A distance between photoresist patterns 140 may be larger than the line distance between thin film patterns which may be finally formed. If a line distance between the final thin film patterns is set to be 100 nm, the distance between photoresist patterns 140 may be formed to be 100 nm or more. A distance between photoresist patterns 140 may be narrow as a desired line distance (100 nm) with a by-product of plasma.

Referring to FIG. 5b, antireflective coating 130 may be etched, for example using photoresist patterns 140 as an etching mask, thereby forming antireflective coating patterns 130a.

Referring to FIG. 5c, before performing an etching process of thin film 120, by-product 150 produced by performing a plasma treatment with respect to photoresist patterns 140 may be attached on an outer wall of photoresist pattern 140. In embodiments, C₅F₈ plasma may be used in the plasma treatment. A CxFy based by-product may be produced due to a reaction between a photoresist layer and C₅F₈ plasma. Since a by-product may have high energy, the by-product may be in a very unstable state. For this reason, a by-product may have a property in which the by product will return to a stable state while discharging its own energy, and the by-product may be discharged to the outside of a process chamber in most processes.

However, according to embodiments, by-product 150 produced by appropriately controlling a process condition may be attached to the outer wall of photoresist pattern 140 in an appropriate thickness.

In embodiments, CCP (Capacitively Coupled Plasma) type plasma equipment (DRM (Dipole Ring Magnetron) produced by TEL) may be used in the plasma treatment. In embodiments, assuming that process conditions include a process chamber pressure of 20 to 40 mTorr, RF power of 500 to 1000 W, C₅F₈ of 5 to 20 sccm, CH₂F₂ of 1 to 20 sccm, Ar of 30 to 300 sccm, and O₂ of 0 to 10 sccm, a thickness of by-product 150 attached to photoresist pattern 140 may be adjusted. Further, the plasma treatment may be performed for approximately 10 to 60 seconds, and a duration for which the plasma treatment may be performed may be appropriately selected depending on the thickness of a desired by-product.

Referring to FIG. 5d, thin film 120 may be etched, for example using photoresist patterns 140 attached with by-product 150 as an etching mask, thereby forming thin film patterns 120a that may be spaced apart from one another at a prescribed interval. The line interval between thin film patterns 120a patterned through the aforementioned method may be narrower than that between photoresist patterns 140.

In embodiments, antireflective coating 130 may be first etched before by-product 150 is attached to photoresist pattern 140. According to embodiments, while antireflective coating 130 is being etched, a portion of thin film 120 positioned beneath a bottom surface of antireflective coating 130 may be etched together.

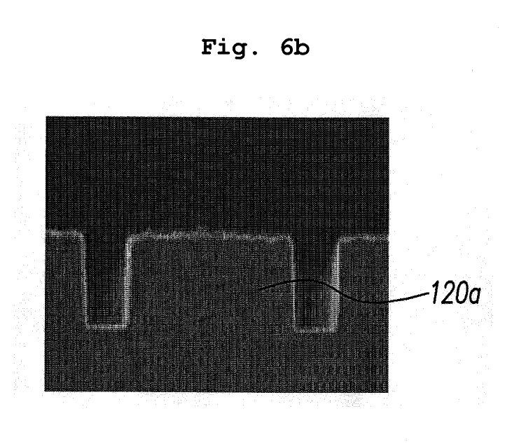

FIG. 6a illustrates an image of a CD-SEM for the thin film pattern 120a in which a step difference 120s occurs. A portion of thin film 120 may be etched while antireflective coating 130 is being etched, and thin film 120 may again be etched, for example using by-product 150 formed in a subsequent process. For this reason, step difference 150s may occur in the thin film pattern 120a. Particularly, in a flash memory device, a shape of a floating gate may influence the performance of the device. If a step difference occurs as shown in FIG. 6a, the performance of a device may be degraded due to the reduction of an amount of electrons stored in a floating gate.

Such a problem may be solved by modifying process conditions in a process of etching antireflective coating 130. According to embodiments, CCP type plasma equipment may be used in the process of etching antireflective coating 130. In embodiments, CF₄ and O₂ gases may be used as a process gas. Particularly, if the flow ratio of CF₄ to O₂ is adjusted 8:1 or more, thin film 120 may be effectively prevented from being etched during the process of etching the antireflective coating. In embodiments, assuming that process conditions include a process chamber pressure of 20 to 80 mTorr, RF power of 500 to 1500 W, CF₄ of 30 to 150 sccm, Ar of 50 to 200 sccm, and O₂ of 5 to 20 sccm, the etching process may be performed for about 5 to 25 seconds.

FIG. 6b illustrates an example in which an antireflective coating may be etched, for example using the aforementioned process conditions, thereby forming thin film patterns 120a through a subsequent process, according to embodiments. As shown in FIG. 6b, if the aforementioned process conditions are used, thin film patterns 120a may be formed without a step difference.

According to embodiments, floating gates may be formed at a desired line distance without necessitating high-priced exposure equipment when forming floating gates at a line distance of 100 nm or less in a semiconductor device, particularly a flash memory device. If a by-product of plasma is attached to a photoresist pattern such that the by-product of plasma is used as an etching mask in embodiments, in occurrence of a step difference may be effectively reduced and/or prevented by etching a portion of a thin film positioned beneath a bottom surface of an antireflective coating while etching the antireflective coating.

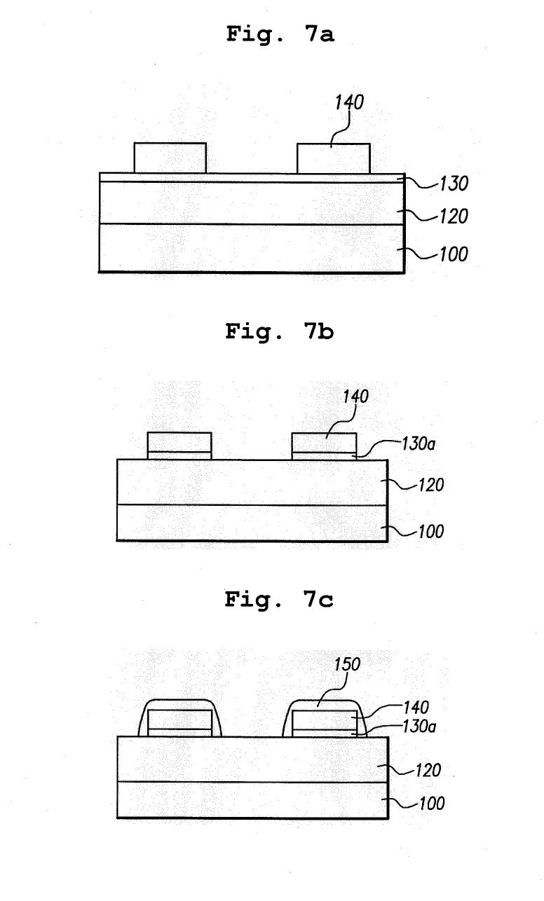

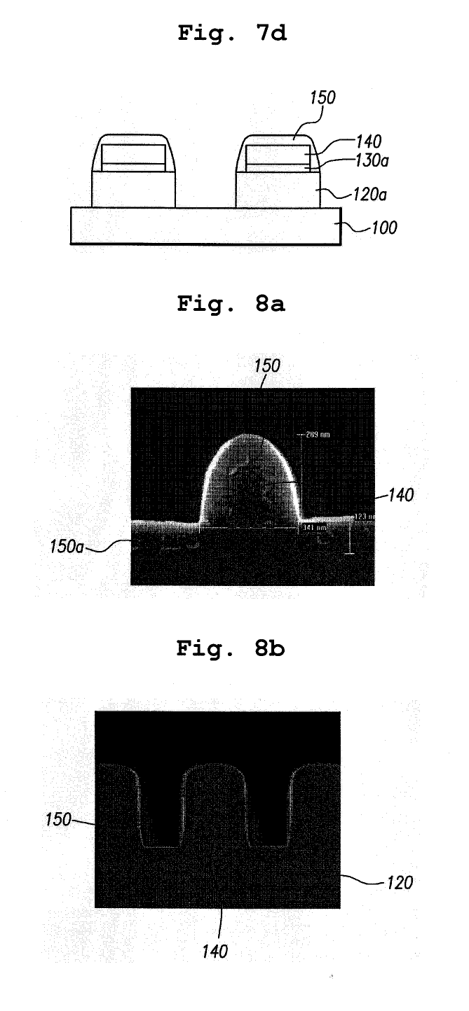

Referring to FIG. 7a, according to embodiments, thin film 120, which may serve as a target object to be etched, may be formed on substrate 100. In embodiments, thin film 120 maybe a polycrystalline silicon layer constituting floating gates of a flash memory device. In addition, thin film 120 may be various kinds of layers to be patterned at a fine distance, but a material of thin film 120 is not limited. Further, thin film 120 may be formed through physical vapor deposition, chemical physical vapor deposition, atomic layer deposition or the like depending on a property of its material.

When developing the photoresist layer in a subsequent photo process, unexpected horizontal and vertical bends may be produced on a sidewall of a photoresist pattern due to the diffused reflection and high reflection of a substrate. This may influence subsequent processes. In embodiments, antireflective coating 130 may be formed on thin film 120 before forming a photoresist pattern.

Photoresist patterns 140 may be formed on thin film 120 through a general photo process. A distance between photoresist patterns 140 may be larger than the line distance between thin film patterns which may be formed. If the line distance between the final thin film patterns is set to be 100 nm, a distance between photoresist patterns 140 may be formed to be 100 nm or more. A distance between photoresist patterns 140 may be narrow as a desired line distance (100 nm) with a by-product of plasma.

Referring to FIG. 7b, antireflective coating 130 may be etched, for example using photoresist patterns 140 as an etching mask, thereby forming antireflective coating patterns 130a. In embodiments, CCP type plasma equipment may be used in the process of etching antireflective coating 130. In embodiments, CF₄ and O₂ gases may be used as a process gas. In embodiments, if the flow ratio of CF₄ to O₂ is adjusted 8:1 or more, thin film 120 may be effectively prevented from being etched during the process of etching the antireflective coating. In embodiments, assuming that process conditions include a process chamber pressure of 30 to 100 mTorr, RF power of 300 to 1500 W, CF₄ of 30 to 200 sccm, Ar of 50 to 300 sccm, and O₂ of 5 to 30 sccm, the etching process may be performed for about 5 to 25 seconds.

Referring to FIG. 7c, before performing an etching process of thin film 120, by-product 150, which may be produced by performing a plasma treatment with respect to photoresist patterns 140, may be attached to an outer wall of photoresist pattern 140. In embodiments, C₅F₈ plasma may be used in the plasma treatment. A CxFy based by-product may be produced due to a reaction between a photoresist layer and C₅F₈ plasma. Since a by-product generally may have high energy, the by-product may be in a very unstable state. For this reason, a by-product may have a property in which the by product may return to a stable state while discharging its own energy, and the by-product may be discharged to the outside of a process chamber in most processes.

However, according to embodiments, by-product 150 produced by controlling a process condition may be attached to an outer wall of photoresist pattern 140 in a prescribed thickness.

In embodiments, the by-product may be attached not only on an outer wall of photoresist pattern 140 but also on a top surface of thin film 120. If the by-product is attached on a surface of thin film 120, the thin film may not be appropriately etched in a subsequent etching process.

FIG. 8a illustrates an image of a CD-SEM for a state where a by-product 150 may be formed not only on a photoresist pattern but also on a thin film 120. This may form bridge 150a between the by-products formed on adjacent photoresist patterns 140.

In embodiments, to prevent bridge 150a of the by-product from being produced, a process gas for forming the by-product and an amount of ions having linearity may be adjusted such that the by-product is not formed on thin film 120. In embodiments, Ar and fluorocarbon gases may be used in the plasma treatment of a photoresist layer, and the flow rate of the Ar gas may be controlled to be five times or less that that of the fluorocarbon gas.

FIG. 8b illustrates an image of a CD-SEM for a state where a by-product 150 is attached on a photoresist pattern 140 by using CCP (Capacitively Coupled Plasma) type plasma equipment (DRM (Dipole Ring Magnetron) produced by TEL). In embodiments, assuming that process conditions include a process chamber pressure of 10 to 50 mTorr, RF power of 300 to 1500 W, C₅F₈ of 5 to 30 sccm, CH₂F₂ of 1 to 20 sccm, Ar of 30 to 200 sccm, and O₂ of 0 to 10 sccm, the plasma treatment may be performed for about 10 to 60 seconds. In embodiments, they flow ratio of Ar to C₅F₈ may be set to 5:1 or less.

Comparing FIGS. 8a and 8b, bridge 150a of the by-product may be formed on thin film 120 in about 1200 Å or more in FIG. 8a, while bridge 150a is not formed, but by-product 150 is selectively attached on only an outer wall of photoresist pattern 140 in FIG. 8b.

As shown in FIG. 7d, thin film 120 may be etched, for example using photoresist patterns 140 attached with by-product 150 as an etching mask, and may form thin film patterns 120a spaced apart from one another at a prescribed interval. The line interval between thin film patterns 120a patterned through the aforementioned method may be narrower than that between photoresist patterns 140.

According to embodiments, floating gates may be formed at a desired line distance without necessitating high-priced exposure equipment when forming floating gates at a line distance of 100 nm or less in a semiconductor device, particularly a flash memory device. In embodiments, if a by-product of plasma is attached on a photoresist pattern such that the by-product of plasma may be used as an etching mask, court to embodiments, a by-product may not be formed on a thin film serving as a target object to be etched but may be selectively formed on only an outer wall of the photoresist pattern.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method comprising:
forming a thin film on a substrate;
forming photoresist patterns over the thin film;
performing a plasma treatment with respect to the photoresist pattern such that a by-product is attached to an outer surface of the photoresist pattern; and
patterning the thin film using the photoresist patterns with the attached by-product as an etching mask.

2. The method of claim 1, further comprising:
forming an antireflective coating on the thin film;
forming photoresist patterns over the antireflective coating; and
patterning the antireflective coating using the photoresist patterns with the attached by-product as an etching mask.

3. The method of claim 1, wherein C₅F₈ plasma is used to perform the plasma treatment.

4. The method of claim 1, wherein CCP type plasma equipment is used to perform the plasma treatment.

5. The method of claim 1, wherein a thickness of the by-product attached to the photoresist pattern is adjusted by changing at least one of a chamber pressure, a flow rate of C₅F₈ gas, a flow rate of Ar gas, and an RF power when performing a plasma treatment.

6. The method of claim 5, wherein the plasma treatment is performed at a pressure of 20 to 40 mTorr, C₅F₈ of 16 to 20 sccm, Ar of 70 to 130 sccm, and an RF power of 500 to 900 W.

7. A method comprising:
forming a thin film serving as a target object to be etched on a substrate;
forming an antireflective coating over the thin film;
forming photoresist patterns on the antireflective coating;
etching the antireflective coating using the photoresist patterns as an etching mask;
performing a plasma treatment with respect to the photoresist patterns such that a by-product is attached to outer walls of the photoresist patterns; and
patterning the thin film using the photoresist patterns with the attached by-product as an etching mask.

8. The method of claim 7, wherein CCP type plasma equipment is used to etch the antireflective coating, perform the plasma treatment, and pattern the thin film.

9. The method of claim 7, wherein CF₄ and O₂ gases are used to etch the antireflective coating.

10. The method of claim 9, wherein a flow ratio of CF₄ to O₂ is at least 8:1.

11. The method of claim 9, wherein etching the antireflective coating is performed at a pressure of 20 to 80 mTorr, an RF power of 500 to 1500 W, CF₄ of 30 to 150 sccm, Ar of 50 to 200 sccm, and O₂ of 5 to 20 sccm.

12. The method of claim 9, wherein the plasma treatment is performed at a pressure of 20 to 40 mTorr, C₅F₈ of 5 to 20 sccm, Ar of 30 to 300 sccm, and an RF power of 500 to 1000 W.

13. A method comprising:
forming a thin film to serve as a target object to be etched on a substrate;
forming an antireflective coating over the thin film;
forming photoresist patterns over the antireflective coating;
etching the antireflective coating using the photoresist patterns as an etching mask;
performing a plasma treatment with respect to the photoresist patterns using Ar and C₅F₈ gases, and adjusting the flow ratio of Ar to C₅F₈ to 5:1 or less such that a by-product is attached to outer walls of the photoresist patterns; and
patterning the thin film using the photoresist patterns with the attached by-product as an etching mask.

14. The method of claim 13, wherein CCP type plasma equipment is used to etch the antireflective coating, perform the plasma treatment, and pattern the thin film.

15. The method of claim 13, wherein etching the antireflective coating is performed at a pressure of 30 to 100 mTorr, an RF power of 300 to 1500 W, CF₄ of 30 to 200 sccm, Ar of 50 to 300 sccm, and O₂ of 5 to 30 sccm.

16. The method of claim 13, wherein the plasma treatment is performed at a pressure of 10 to 50 mTorr, C₅F₈ of 5 to 30 sccm, Ar of 30 to 200 sccm, and RF power of 300 to 1500 W.
